(19) United States
(12) Patent Application Publication
(10) Pub. No.: US 2026/0304784 A1
(43) Pub. Date: Oct. 1, 2026

(54) MAGNETORESISTANCE CHANGE ELEMENT AND MAGNETIC ARRAY

(71) Applicant: TDK Corporation, Tokyo (JP)

(72) Inventor: Keita SUDA, Tokyo (JP)

(73) Assignee: TDK Corporation, Tokyo (JP)

(21) Appl. No.: 19/091,892

(22) Filed: Mar. 27, 2025

(51) Int. Cl. H10B 61/00; H10N 50/10; H10N 50/85

(52) U.S. Cl. CPC H10B 61/20; H10N 50/10; H10N 50/85

(57) ABSTRACT

This magnetoresistance change element includes a spin-orbit torque wiring and a laminate. The laminate has a first ferromagnetic layer. The spin-orbit torque wiring and the first ferromagnetic layer form a Schottky junction.

### TECHNICAL FIELD

The present disclosure relates to a magnetoresistance change element and a magnetic array.

### BACKGROUND ART

Giant magnetoresistance (GMR) elements constituted of a multilayer film having ferromagnetic layers and a nonmagnetic layer, and tunnel magnetoresistance (TMR) elements using an insulating layer (a tunnel barrier layer, a barrier layer) as a nonmagnetic layer are known as magnetoresistance effect elements. Magnetoresistance effect elements can be applied to magnetic sensors, high-frequency components, magnetic heads, and magnetic random-access memories (MRAM).

An MRAM is a storage element in which a magnetoresistance effect element is integrated. An MRAM allows reading and writing of data utilizing characteristics of magnetoresistance effect elements whose resistance varies if magnetization directions of two ferromagnetic layers sandwiching a nonmagnetic layer therebetween in a magnetoresistance effect element change. For example, the magnetization directions of ferromagnetic layers are controlled utilizing a magnetic field generated by a current. In addition, for example, the magnetization directions of ferromagnetic layers are controlled utilizing a spin transfer torque (STT) generated when a current flows in a lamination direction of a magnetoresistance effect element.

When the magnetization directions of ferromagnetic layers are rewritten utilizing an STT, a current is caused to flow in the lamination direction of a magnetoresistance effect element. A writing current may cause deterioration in characteristics of the magnetoresistance effect element.

In recent years, attention has been focused on methods requiring no current to flow in the lamination direction of a magnetoresistance effect element at the time of writing (for example, Patent Document 1). One of the methods is a writing method utilizing a spin-orbit torque (SOT). An SOT is induced due to a spin current generated by a spin-orbit interaction or a Rashba effect in an interface between different kinds of materials. A current for inducing an SOT into a magnetoresistance effect element flows in a direction intersecting the lamination direction of the magnetoresistance effect element. That is, there is no need for a current to flow in the lamination direction of the magnetoresistance effect element, and thus an extended lifespan of the magnetoresistance effect element is expected.

### CITATION LIST

### Patent Document

Patent Document 1: Japanese Unexamined Patent Application, First Publication No. 2017-216286

### SUMMARY

### Technical Problem

A magnetic memory has a plurality of integrated magnetoresistance effect elements. If the amount of current applied to each of the magnetoresistance effect elements increases, power consumption of the magnetic memory increases. There is a demand to reduce the amount of current applied to each of magnetoresistance effect elements and restrain power consumption of a magnetic memory.

The present disclosure has been made in consideration of the foregoing circumstances, and an object thereof is to provide a magnetoresistance change element and a magnetic array operated with a small amount of current.

### Solution to Problem

A magnetoresistance change element according to a first aspect includes a spin-orbit torque wiring and a laminate. The laminate has a first ferromagnetic layer. The spin-orbit torque wiring and the first ferromagnetic layer form a Schottky junction.

### Advantageous Effects of Invention

The magnetoresistance change element and the magnetic array according to the present disclosure can be operated with a small amount of current.

### BRIEF DESCRIPTION OF DRAWINGS

FIG. 1 A circuit diagram of a magnetic memory according to a first embodiment.

FIG. 2 A cross-sectional view of a characteristic portion of the magnetic memory according to the first embodiment.

FIG. 3 A cross-sectional view of a magnetoresistance effect element according to the first embodiment.

FIG. 4 A plan view of the magnetoresistance effect element according to the first embodiment.

FIG. 5 A cross-sectional view of a magnetoresistance effect element according to a first modification example.

FIG. 6 A cross-sectional view of a magnetoresistance effect element according to a second modification example.

FIG. 7 A cross-sectional view of a magnetoresistance effect element according to a second embodiment.

FIG. 8 A cross-sectional view of a magnetization rotation element according to a third embodiment.

### DESCRIPTION OF EMBODIMENTS

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present disclosure is not limited thereto and can be suitably changed and performed within a range in which the effects of the present disclosure are exhibited.

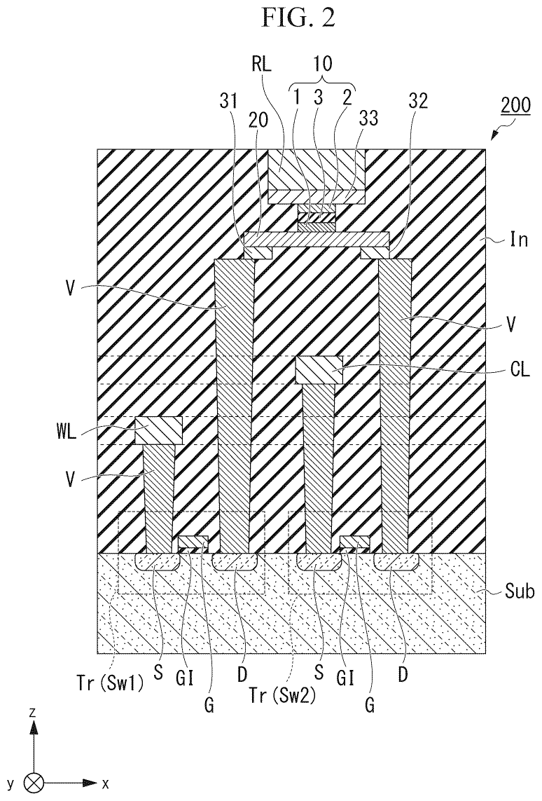

First, directions will be defined. One direction on a surface of a substrate Sub, which will be described below (refer to FIG. 2), will be regarded as an x direction, and a direction orthogonal to the x direction will be regarded as a y direction. For example, the x direction is a direction from a first electrode 31 toward a second electrode 32. A z direction is a direction orthogonal to the x direction and the y direction. The z direction is an example of a lamination direction in which layers are laminated. Hereinafter, the positive z direction may be expressed as “upward”, and the negative z direction may be expressed as “downward”. The upward-downward direction does not necessarily coincide with a direction in which gravity is applied.

In this specification, for example, the expression “extending in the x direction” means that the dimension in the x direction is larger than the smallest dimension of the dimensions in the x direction, the y direction, and the z direction. The same applies to the cases of extending in other directions. In addition, in this specification, the term “connection” is not limited to a case of being physically connected. For example, the term “connection” is not limited to a case in which two layers are physically in contact with each other, and it also includes a case in which two layers are connected to each other with another layer sandwiched therebetween. In addition, in this specification, the term “connection” also includes electrical connection.

### First Embodiment

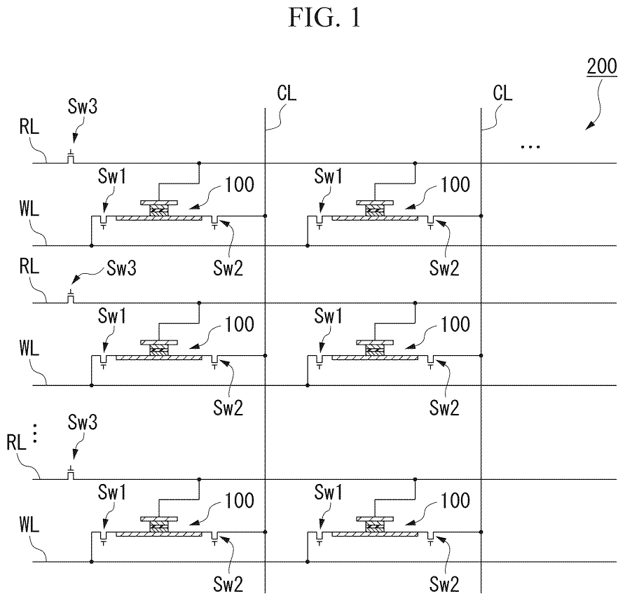

FIG. 1 is a view of the constitution of a magnetic memory 200 according to a first embodiment. The magnetic memory 200 includes a plurality of magnetoresistance effect elements 100, a plurality of writing lines WL, a plurality of common lines CL, a plurality of reading lines RL, a plurality of first switching elements Sw1, a plurality of second switching elements Sw2, and a plurality of third switching elements Sw3. For example, the magnetic memory 200 is a magnetic array in which the magnetoresistance effect elements 100 are arrayed in an array shape. The magnetoresistance effect element 100 is an example of a magnetoresistance change element.

The writing lines WL each electrically connect a power source to one or more magnetoresistance effect elements 100. The common lines CL each serve as a wiring used at times of both writing and reading data. The common lines CL each electrically connect a reference potential to one or more magnetoresistance effect elements 100. For example, the reference potential is a ground potential. The common line CL may be provided in each of the plurality of magnetoresistance effect elements 100 or may be provided across the plurality of magnetoresistance effect elements 100. The reading lines RL each electrically connect the power source to one or more magnetoresistance effect elements 100. The power source is connected to the magnetic memory 200 when in use.

The magnetoresistance effect elements 100 are each connected to the first switching element Sw1, the second switching element Sw2, and the third switching element Sw3. The first switching element Sw1 is connected between the magnetoresistance effect element 100 and the writing line WL. The second switching element Sw2 is connected between the magnetoresistance effect element 100 and the common line CL. The third switching element Sw3 is connected to the reading line RL across the plurality of magnetoresistance effect elements 100.

If the first switching element Sw1 and the second switching element Sw2 are turned on, a writing current flows between the writing line WL and the common line CL connected to a predetermined magnetoresistance effect element 100. Due to a writing current flowing therethrough, data is written in the predetermined magnetoresistance effect element 100. If the second switching element Sw2 and the third switching element Sw3 are turned on, a reading current flows between the common line CL and the reading line RL connected to a predetermined magnetoresistance effect element 100. Due to a reading current flowing therethrough, data is read from the predetermined magnetoresistance effect element 100.

The first switching element Sw1, the second switching element Sw2, and the third switching element Sw3 are elements for controlling a flow of a current. For example, the first switching element Sw1, the second switching element Sw2, and the third switching element Sw3 are transistors. The first switching element Sw1, the second switching element Sw2, and the third switching element Sw3 may be elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

In the magnetic memory 200 shown in FIG. 1, the magnetoresistance effect elements 100 connected to the same wiring share the third switching element Sw3. The third switching element Sw3 may be provided in each of the magnetoresistance effect elements 100. In addition, the third switching element Sw3 may be provided in each of the magnetoresistance effect elements 100, and the first switching element Sw1 or the second switching element Sw2 may be shared by the magnetoresistance effect element 100 connected to the same wiring.

FIG. 2 is a cross-sectional view of a characteristic portion of the magnetic memory 200 according to the first embodiment. FIG. 2 is a cross section of the magnetoresistance effect element 100 cut along an xz plane passing through the center of the width of a spin-orbit torque wiring 20 (which will be described below) in the y direction.

The first switching element Sw1 and the second switching element Sw2 shown in FIG. 2 are transistors Tr. The third switching element Sw3 is electrically connected to the reading line RL and is located, for example, at a different position in the y direction in FIG. 2. For example, the transistors Tr are field effect transistors each having a gate electrode G, a gate insulating film GI, and a source S and a drain D formed on the substrate Sub. The source S and the drain D are prearranged depending on a flowing direction of a current, and these are the same regions. The positional relationship between the source S and the drain D may be reversed. For example, the substrate Sub is a semiconductor substrate.

The transistor Tr and the magnetoresistance effect element 100 are electrically connected via a via wiring V, the first electrode 31, and the second electrode 32. In addition, the transistor Tr and the writing line WL or the common line CL are connected via the via wiring V. For example, the via wiring V extends in the z direction. The reading line RL is connected to a laminate 10 via a third electrode 33. The via wiring V, the first electrode 31, the second electrode 32, and the third electrode 33 contain a conductive material.

Areas around the magnetoresistance effect element 100 and the transistors Tr are covered by an insulating layer In. The insulating layer In is an insulating layer providing insulation between wirings of a multilayer wiring or between elements. For example, the insulating layer In is made of silicon oxide (SiOₓ), silicon nitride (SiNₓ), silicon carbide (SiC), chromium nitride (CrN), silicon carbonitride (SiCN), silicon oxynitride (SiON), aluminum oxide (Al₂O₃), zirconium oxide (ZrOₓ), magnesium oxide (MgO), aluminum nitride (AlN), or the like.

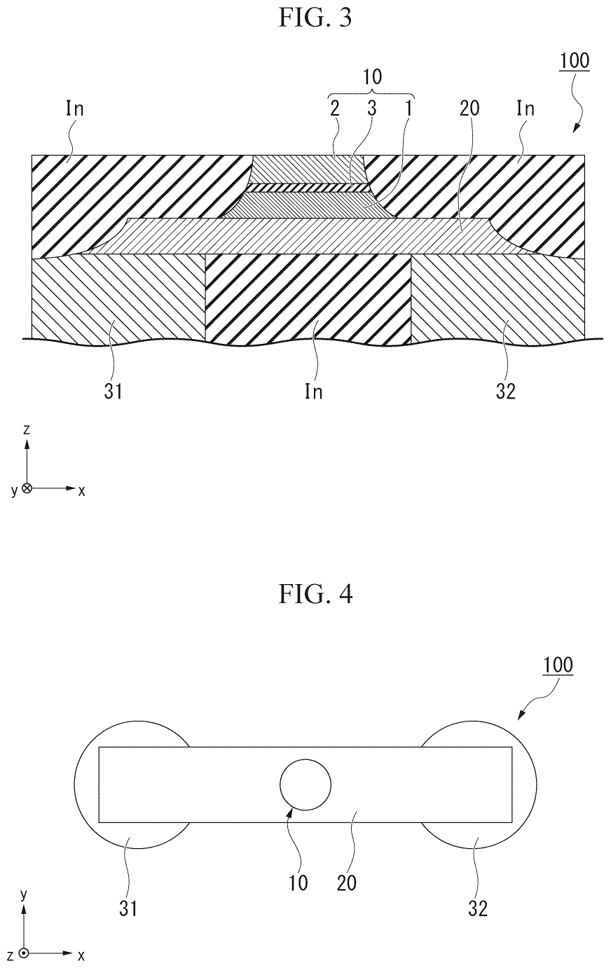

FIG. 3 is a cross-sectional view of the magnetoresistance effect element 100. FIG. 3 is a cross section of the magnetoresistance effect element 100 cut along an xz plane passing through the center of the width of the spin-orbit torque wiring 20 in the y direction. FIG. 4 is a plan view of the magnetoresistance effect element 100 viewed in the z direction.

For example, the magnetoresistance effect element 100 includes the laminate 10 and the spin-orbit torque wiring 20. The laminate 10 are laminated on the spin-orbit torque wiring 20.

The resistance value of the laminate 10 in the z direction varies when spins are injected into the laminate 10 from the spin-orbit torque wiring 20. The magnetoresistance effect element 100 is a magnetic element utilizing a spin-orbit torque (SOT) and may be referred to as a spin-orbit torque-type magnetoresistance effect element, a spin injection-type magnetoresistance effect element, or a spin current magnetoresistance effect element.

The laminate 10 is sandwiched between the spin-orbit torque wiring 20 and the third electrode 33 (refer to FIG. 2) in the z direction. The laminate 10 is a columnar body. For example, the shape of the laminate 10 in a planar view in the z direction is a circular shape, an oval shape, or a quadrangular shape. For example, side surfaces of the laminate 10 are inclined with respect to the z direction.

For example, the laminate 10 has a first ferromagnetic layer 1, a second ferromagnetic layer 2, and a nonmagnetic layer 3. For example, the first ferromagnetic layer 1 comes into contact with the spin-orbit torque wiring 20 and is laminated on the spin-orbit torque wiring 20. Spins are injected into the first ferromagnetic layer 1 from the spin-orbit torque wiring 20. The magnetization of the first ferromagnetic layer 1 receives a spin-orbit torque (SOT) due to injected spins so that an orientation direction thereof varies. The first ferromagnetic layer 1 and the second ferromagnetic layer 2 sandwich the nonmagnetic layer 3 in the z direction.

The first ferromagnetic layer 1 and the second ferromagnetic layer 2 each has magnetization. The orientation direction of the magnetization of the second ferromagnetic layer 2 is less likely to vary than that of the magnetization of the first ferromagnetic layer 1 when a predetermined external force is applied. The first ferromagnetic layer 1 may be referred to as a magnetization free layer, and the second ferromagnetic layer 2 may be referred to as a magnetization fixed layer or a magnetization reference layer. In the laminate 10 shown in FIG. 3, the magnetization fixed layer is located on a side away from the substrate Sub and is referred to as a top pin structure. The resistance value of the laminate 10 varies in accordance with the difference in the relative angle of magnetization between the first ferromagnetic layer 1 and the second ferromagnetic layer 2 sandwiching the nonmagnetic layer 3 therebetween.

The first ferromagnetic layer 1 and the second ferromagnetic layer 2 contain a ferromagnetic body. For example, the ferromagnetic body is a metal selected from the group consisting of Cr, Mn, Co, Fe, and Ni; an alloy containing one or more kinds of these metals; an alloy containing at least one or more kinds of elements of these metals, B, C, and N; or the like. For example, the ferromagnetic body is an alloy of Co—Fe, Co—Fe—B, Ni—Fe, or Co—Ho; a Sm—Fe alloy; a Fe—Pt alloy; a Co—Pt alloy; or a CoCrPt alloy. For example, the first ferromagnetic layer 1 and the second ferromagnetic layer 2 are metal magnetic bodies.

The first ferromagnetic layer 1 and the second ferromagnetic layer 2 may contain a Heusler alloy. The Heusler alloy contains an intermetallic compound having a chemical composition of XYZ or X₂YZ. X represents a transition metal element or a noble metal element of the Co group, the Fe group, the Ni group, or the Cu group on the periodic table. Y represents a transition metal of the Mn group, the V group, the Cr group, or the Ti group, or a kind of an element represented by X. Z represents a typical element of Group III to Group V. For example, the Heusler alloy consists of Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The nonmagnetic layer 3 contains a nonmagnetic body. When the nonmagnetic layer 3 is an insulator (when it is a tunnel barrier layer), for example, Al₂O₃, SiO₂, MgO, MgAl₂O₄, or the like can be used as a material thereof. In addition to these, a material or the like in which a part of Al, Si, or Mg is replaced with Zn, Be, or the like can also be used. Among these, since MgO and MgAl₂O₄ are materials which can realize coherent tunneling, spins can be efficiently injected. When the nonmagnetic layer 3 is made of a metal, Cu, Au, Ag, or the like can be used as a material thereof. Moreover, when the nonmagnetic layer 3 is constituted of a semiconductor, Si, Ge, CuInSe₂, CuGaSe₂, Cu(In, Ga)Se₂, or the like can be used as a material thereof.

The laminate 10 may have a layer other than the first ferromagnetic layer 1, the second ferromagnetic layer 2, and the nonmagnetic layer 3. For example, a base layer may be provided between the spin-orbit torque wiring 20 and the first ferromagnetic layer 1. The base layer enhances the crystallinity of the layers constituting the laminate 10. In addition, for example, the laminate 10 may have a cap layer on its top surface.

In addition, in the laminate 10, a ferromagnetic layer may be provided on a surface of the second ferromagnetic layer 2 on a side opposite to the nonmagnetic layer 3 with a spacer layer therebetween. The second ferromagnetic layer 2, the spacer layer, and the ferromagnetic layer form a synthetic antiferromagnetic structure (SAF structure). The synthetic antiferromagnetic structure is constituted of two magnetic layers sandwiching a nonmagnetic layer therebetween. Due to antiferromagnetic coupling between the second ferromagnetic layer 2 and the ferromagnetic layer, the coercivity of the second ferromagnetic layer 2 further increases than in the case of having no ferromagnetic layer. For example, the ferromagnetic layers are made of IrMn, PtMn, or the like. For example, the spacer layer contains at least one selected from the group consisting of Ru, Ir, and Rh.

The spin-orbit torque wiring 20 comes into contact with the laminate 10. For example, the spin-orbit torque wiring 20 comes into contact with the first ferromagnetic layer 1 of the laminate 10. For example, in the spin-orbit torque wiring 20, the length in the x direction is longer than that in the y direction and extends in the x direction when viewed in the z direction. A writing current flows in the x direction of the spin-orbit torque wiring 20. At least a part of the spin-orbit torque wiring 20 sandwiches the first ferromagnetic layer 1 together with the nonmagnetic layer 3 in the z direction.

The spin-orbit torque wiring 20 generates a spin current due to a spin Hall effect when a current flows and injects spins into the first ferromagnetic layer 1. For example, the spin-orbit torque wiring 20 applies a spin-orbit torque (SOT) to the magnetization of the first ferromagnetic layer 1 by an amount with which the magnetization of the first ferromagnetic layer 1 can be reversed. The spin Hall effect is a phenomenon in which a spin current is induced in a direction orthogonal to the flowing direction of a current based on a spin-orbit interaction when a current flows. The spin Hall effect is in common with a normal Hall effect in that moving (migrating) charge (electrons) can bend the moving (migrating) direction. The normal Hall effect causes the moving direction of moving charged particles in a magnetic field to bend by means of a Lorentz force. In contrast, the spin Hall effect causes the moving direction of spins to bend simply by means of moving electrons (flowing currents) even if there is no magnetic field.

For example, if a current flows in the spin-orbit torque wiring 20, first spins oriented in one direction and second spins oriented in a direction opposite to that of the first spins individually bend in a direction orthogonal to the flowing direction of a current I due to the spin Hall effect. For example, the first spins oriented in the negative y direction bend in the positive z direction, and the second spins oriented in the positive y direction bend in the negative z direction.

In a nonmagnetic body (a material that is not a ferromagnetic body), the number of electrons in the first spins and the number of electrons in the second spins generated due to the spin Hall effect are the same. That is, the number of electrons in the first spins toward the positive z direction and the number of electrons in the second spins toward the negative z direction are the same. The first spins and the second spins flow in directions in which an uneven distribution of the spins is eliminated. Since flows of charge are offset each other in movement of the first spins and the second spins in the z direction, the current amount becomes zero. A spin current accompanying no current is particularly referred to as a pure spin current.

When a flow of electrons in the first spins is expressed as J_{↑}, a flow of electrons in the second spins is expressed as J_{↓}, and a spin current is expressed as J_{S}, these are defined as J_{S}=J_{↑}−J_{↓}. The spin current J_{S} is generated in the z direction. The first spins are injected into the first ferromagnetic layer 1 from the spin-orbit torque wiring 20.

The spin-orbit torque wiring 20 and the first ferromagnetic layer 1 form a Schottky junction. A Schottky junction is a junction between a metal and a semiconductor exhibiting a rectifying effect.

In a Schottky junction interface, electrons are likely to flow from the semiconductor toward the metal (forward direction) but are unlikely to flow from the metal toward the semiconductor (reverse direction). If the spin-orbit torque wiring 20 and the first ferromagnetic layer 1 form a Schottky junction, a split of a part of a writing current flowing along the spin-orbit torque wiring 20 into the first ferromagnetic layer 1 can be curbed. When a writing current is applied to the spin-orbit torque wiring 20, the amount of current flowing in the spin-orbit torque wiring 20 is larger than the amount of current flowing in the first ferromagnetic layer 1.

For example, the spin-orbit torque wiring 20 is a semiconductor. For example, the spin-orbit torque wiring 20 may be a p-type semiconductor or an n-type semiconductor. The spin-orbit torque wiring 20 (semiconductor) and the first ferromagnetic layer 1 (metal) form a Schottky junction.

The difference between a work function of the material constituting the spin-orbit torque wiring 20 and a work function of the material constituting the first ferromagnetic layer 1 is preferably 0.4 eV or larger, for example, and is more preferably 1.0 eV or larger. A larger difference between the work functions of two layers makes it possible to further curb a split of a part of a writing current flowing along the spin-orbit torque wiring 20 into the first ferromagnetic layer 1.

For example, it is preferable that the spin-orbit torque wiring 20 contain a material whose work function significantly differs from that of the first ferromagnetic layer 1. For example, the spin-orbit torque wiring 20 may be, for example, an oxide containing copper, an oxide containing nickel, an oxide containing zinc, an oxide containing cobalt, an oxide containing vanadium, an oxide containing manganese, an oxide containing iron, an oxide containing tin, an oxide containing indium, an oxide containing titanium, an oxide containing cadmium oxide, gallium-containing oxide, cerium-containing oxide, and tungsten-containing oxide. Oxides containing copper, nickel, cobalt, vanadium, manganese, iron, and tin are primarily p-type semiconductors, while oxides containing zinc, indium, titanium, cadmium, gallium, cerium, and tungsten are primarily n-type semiconductors.

Oxides containing copper include, for example, CuO, Cu₂°, CuAlO₂, CuCrO₂, CuFeO₂, CuGaO₂, CuInO₂, CuScO₂, CuYO₂, CuLaO₂. Oxides containing nickel include, for example, NiO, LiNiO₂, NiCoO₄, NiFe₂O₄, NiZnO, NiTiO₃, NiSb₂O₆, NiWO₄, and NiNb₂O₆. Oxides containing zinc include ZnO, Zn₂SnO₄, ZnIn₂O₄, ZnFeO₄, ZnTiO₃, ZnAl₂O₄, ZnCo₂O₄, ZnNi₂O₄, and ZnMn₂O₄. Oxides containing other metal can likewise be partially substituted for the base metal oxide.

The spin-orbit torque wiring 20 may contain, for example, any one selected from the group consisting of CuO, Cu₂O, NiO, CuFeO₂, CuAlO₂, and CuGaO₂. These materials are likely to form a Schottky junction with the first ferromagnetic layer 1.

For example, when the first ferromagnetic layer 1 is made of Co—Fe—B, the spin-orbit torque wiring 20 may be the p-type semiconductor described above.

For example, the spin-orbit torque wiring 20 may contain an element constituting the first ferromagnetic layer 1 as a dopant. For example, when the spin-orbit torque wiring 20 is an n-type semiconductor and the first ferromagnetic layer 1 is made of Co—Fe—B, boron may be injected into the spin-orbit torque wiring 20 as a dopant. The resistance of the spin-orbit torque wiring 20 declines by injecting a dopant into the spin-orbit torque wiring 20. It is preferable that the concentration of the dopant in the spin-orbit torque wiring 20 be higher as it is closer to the first ferromagnetic layer 1.

For example, the thickness of the spin-orbit torque wiring 20 is 4 nm or larger. For example, the thickness of the spin-orbit torque wiring 20 may be 20 nm or smaller.

Each of the first electrode 31 and the second electrode 32 is connected to the spin-orbit torque wiring 20. The first electrode 31 and the second electrode 32 are connected to the spin-orbit torque wiring 20 at positions sandwiching the laminate 10 therebetween when viewed in the z direction. It is preferable that the first electrode 31 and the second electrode 32 contain a material having excellent conductivity.

It is preferable that at least one of the interface between the first electrode 31 and the spin-orbit torque wiring 20 and the interface between the second electrode 32 and the spin-orbit torque wiring 20 forms an ohmic junction. In addition, it is preferable that both the interfaces form an ohmic junction. An ohmic junction is a junction between a metal and a semiconductor in which a current can flow in both the forward direction and the reverse direction. If these interfaces form an ohmic junction, occurrence of a current loss in the interface between the first electrode 31 or the second electrode 32 and the spin-orbit torque wiring 20 can be curbed. For example, the first electrode 31 and the second electrode 32 are made of Pt, Al, Au, Ti, Ni, and Cr. The first electrode 31 and the second electrode 32 are not limited when these elements are used as single metals, and may be alloyed with these elements. For example, Ni silicide or Co silicide may be used.

Next, a method for manufacturing the magnetoresistance effect element 100 will be described. The magnetoresistance effect element 100 is formed through a step of laminating the layers and a processing step of processing some of the layers into a predetermined shape. The layers can be laminated using a sputtering method, a chemical vapor deposition (CVD) method, an electron beam evaporation method (EB evaporation method), an atom laser deposition method, or the like. The layers can be processed using photolithography or the like.

First, impurities are doped at predetermined positions on the substrate Sub to form the source S and the drain D. Next, the gate insulating film GI and the gate electrode G are formed between the source S and the drain D. The source S, the drain D, the gate insulating film GI, and the gate electrode G form the transistor Tr.

Next, the insulating layer In is formed such that the transistor Tr is covered. In addition, the via wiring V, the first electrode 31, and the second electrode 32 are formed by forming opening portions in the insulating layer In and filling the insides of the opening portions with conductors. The writing line WL and the common line CL are formed by laminating the insulating layer In to a predetermined thickness, then forming grooves in the insulating layer In, and filling the grooves with conductors.

Next, on surfaces of the insulating layer In, the first electrode 31, and the second electrode 32 on one side, the spin-orbit torque wiring 20, the first ferromagnetic layer 1, the nonmagnetic layer 3, and the second ferromagnetic layer 2 are laminated in this order and processed into a predetermined shape, thereby obtaining the magnetoresistance effect element 100.

Next, operation of the magnetoresistance effect element 100 will be described. The magnetoresistance effect element 100 performs writing of data and reading of data.

When data is written in the magnetoresistance effect element 100, a writing current is caused to flow along the spin-orbit torque wiring 20. The writing current applies a spin-orbit torque to the magnetization of the first ferromagnetic layer 1 and changes the magnetization direction of the first ferromagnetic layer 1, and therefore data is written in the magnetoresistance effect element 100.

A writing current flows when a potential difference occurs between the first electrode 31 and the second electrode 32. For example, when data is rewritten from “0” to “1”, a writing current is caused to flow from the first electrode 31 to the second electrode 32, and when data is rewritten from “1” to “0”, a writing current is caused to flow from the second electrode 32 to the first electrode 31. This relationship may be reversed.

If the spin-orbit torque wiring 20 and the first ferromagnetic layer 1 form a Schottky junction, a split of a part of a current flowing in the spin-orbit torque wiring 20 into the first ferromagnetic layer 1 can be curbed. The current which has split into the first ferromagnetic layer 1 does not contribute to magnetization reversal of the first ferromagnetic layer 1 utilizing a spin-orbit torque. The magnetization of the first ferromagnetic layer 1 can be reversed even with a small writing current by curbing a split into the first ferromagnetic layer 1.

When data is read from the magnetoresistance effect element 100, a reading current caused to flow along the lamination direction of the laminate 10. The resistance value of the laminate 10 differs between cases in which the magnetization of the first ferromagnetic layer 1 and the magnetization of the second ferromagnetic layer 2 are parallel and anti-parallel. The difference in this resistance value can be read as data by causing a reading current to flow in the lamination direction of the laminate 10. The reading current is smaller than the writing current, and the magnetization of the first ferromagnetic layer 1 is not reversed by the reading current.

A reading current flows when a potential difference occurs between the first electrode 31 or the second electrode 32 and the third electrode 33. It is preferable that a reading current is constituted to flow from the spin-orbit torque wiring 20 toward the laminate 10. This flowing direction is the forward direction of a Schottky junction, and a loss of a reading current can be curbed due to the constitution. For example, a reading current flows from the spin-orbit torque wiring 20 toward the laminate 10 by causing the potential of the third electrode 33 to be lower than the potential of the first electrode 31 or the second electrode 32.

As above, in the magnetoresistance effect element 100 according to the first embodiment, a split of a part of a writing current into the first ferromagnetic layer 1 due to a Schottky junction can be curbed. For this reason, in the magnetoresistance effect element 100 according to the first embodiment, the amount of writing current required to reverse the magnetization of the first ferromagnetic layer 1 can be reduced. If the amount of writing current for each element is small, power consumption of the magnetic memory 200 in its entirety can be reduced.

Hereinabove, an example of the magnetoresistance effect element 100 according to the first embodiment has been described. However, addition, omission, replacement, and other changes of the constitutions can be made within a range not departing from the gist of the present disclosure.

### First Modification Example

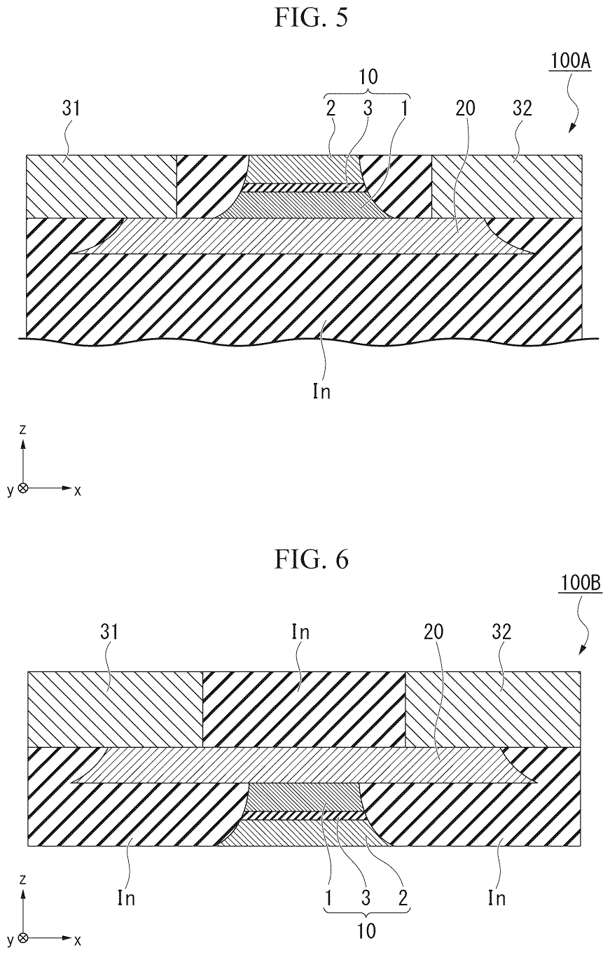

FIG. 5 is a cross-sectional view of a magnetoresistance effect element 100A according to a first modification example. FIG. 5 is an xz cross section passing through the center of the spin-orbit torque wiring 20 in the y direction. In FIG. 5, similar reference signs are applied to the same constitutions as those in FIG. 3, and a description thereof will be omitted.

The magnetoresistance effect element 100A differs from the magnetoresistance effect element 100 in connection positions of the first electrode 31 and the second electrode 32. The first electrode 31 and the second electrode 32 may be connected to any surface of the spin-orbit torque wiring 20.

### Second Modification Example

FIG. 6 is a cross-sectional view of a magnetoresistance effect element 100B according to a second modification example. FIG. 6 is an xz cross section passing through the center of the spin-orbit torque wiring 20 in the y direction. In FIG. 6, similar reference signs are applied to the same constitutions as those in FIG. 3, and a description thereof will be omitted.

The magnetoresistance effect element 100B differs from the magnetoresistance effect element 100 in connection positions of the laminate 10, the first electrode 31, and the second electrode 32. The laminate 10 shown in FIG. 6 has a bottom pin structure in which the magnetization fixed layer (second ferromagnetic layer 2) is closer to the substrate Sub. If the magnetization fixed layer is on the substrate Sub side, magnetization stability of the magnetization fixed layer is enhanced so that the MR ratio of the magnetoresistance effect element 100B is enhanced.

### Second Embodiment

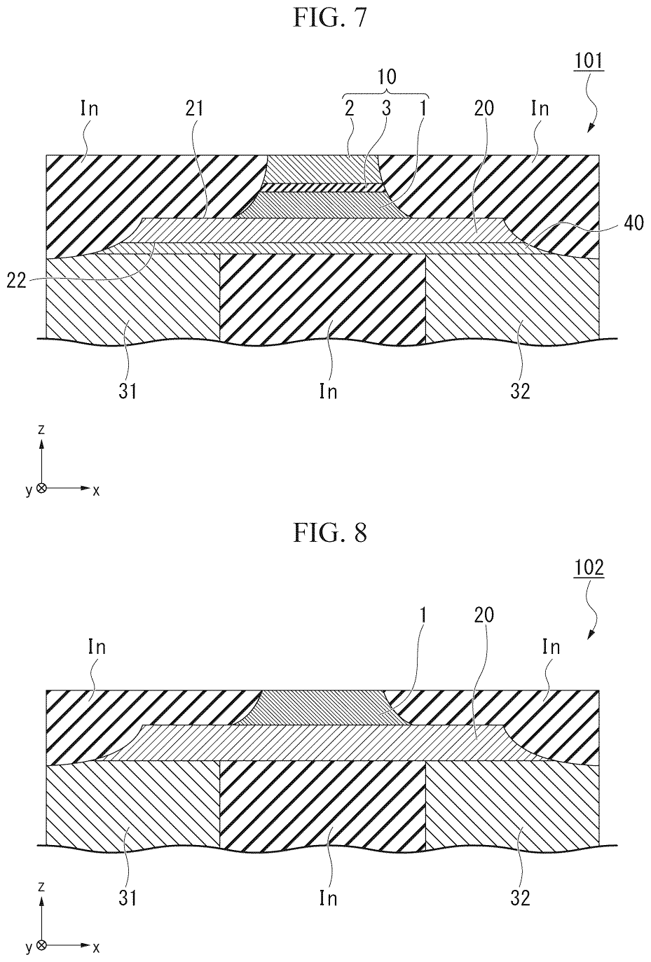

FIG. 7 is a cross-sectional view of a magnetoresistance effect element 101 according to a second embodiment. FIG. 7 is an xz cross section passing through the center of the spin-orbit torque wiring 20 in the y direction. In FIG. 7, similar reference signs are applied to the same constitutions as those in FIG. 3, and description thereof will be omitted. In the magnetic memory 200, the magnetoresistance effect element 101 according to the second embodiment can be replaced with the magnetoresistance effect element 100 according to the first embodiment.

The magnetoresistance effect element 101 differs from the magnetoresistance effect element 100 in further having a buffer layer 40. The buffer layer 40 is connected to a second surface 22 of the spin-orbit torque wiring 20. The second surface 22 is a surface on a side opposite to a first surface 21 on which the first ferromagnetic layer 1 and the spin-orbit torque wiring 20 come into contact with each other. The buffer layer 40 may be formed across the second surface 22 in its entirety or may be located at a position facing the first ferromagnetic layer 1.

When the spin-orbit torque wiring 20 is a p-type semiconductor, the work function of the buffer layer 40 is lower than the work function of the spin-orbit torque wiring 20, and when the spin-orbit torque wiring 20 is an n-type semiconductor, the work function of the buffer layer 40 is higher than the work function of the spin-orbit torque wiring 20.

The difference between the work function of the material constituting the spin-orbit torque wiring 20 and the work function of the material constituting the buffer layer 40 is preferably 0.4 eV or larger, for example, and is more preferably 1.0 eV or larger.

For example, when the spin-orbit torque wiring 20 is a p-type semiconductor, the buffer layer 40 may be made of Au, Pt and Ni, and when the spin-orbit torque wiring 20 is an n-type semiconductor, it may be made of Al, Ti, Ni and Mo.

The buffer layer 40 adjusts the position of a part in the z direction where the potential is low inside the spin-orbit torque wiring 20. Since the spin-orbit torque wiring 20 and the first ferromagnetic layer 1 form a Schottky junction, the potential becomes high in the vicinity of the first ferromagnetic layer 1 of the spin-orbit torque wiring 20. In the buffer layer 40, the work function is adjusted depending on the spin-orbit torque wiring 20, and the potential also becomes high in the vicinity of the buffer layer 40 of the spin-orbit torque wiring 20. Due to the provided buffer layer 40, the position of the part in the z direction where the potential is low inside the spin-orbit torque wiring 20 can be brought closer to the first ferromagnetic layer 1.

Since carriers are likely to flow in a part with a low potential, when the buffer layer 40 is not provided, they flow in the vicinity of the second surface 22. In order to efficiently inject spins generated by the spin-orbit torque wiring 20 into the first ferromagnetic layer 1, it is preferable that carriers (writing current) flow in the vicinity of the first ferromagnetic layer 1. Due to the provided buffer layer 40, the position where a writing current flows inside the spin-orbit torque wiring 20 can be brought closer to the first ferromagnetic layer 1.

The magnetoresistance effect element 101 according to the second embodiment exhibits an effect similar to that of the magnetoresistance effect element 100 according to the first embodiment. In addition, in the magnetoresistance effect element 101 according to the second embodiment, the position where a writing current flows due to the buffer layer 40 is shifted to the first ferromagnetic layer 1 side so that the efficiency of writing data is further enhanced.

In the magnetoresistance effect element 101 according to the second embodiment as well, modification examples similar to those of the magnetoresistance effect element 100 according to the first embodiment can be selected.

### Third Embodiment

FIG. 8 is a cross-sectional view of a magnetization rotation element 102 according to a third embodiment. In FIG. 1, the magnetization rotation element 102 can be replaced by the magnetoresistance effect element 100 according to the first embodiment. The magnetization rotation element 102 is an example of a magnetoresistance change element.

For example, the magnetization rotation element 102 causes light to be incident on the first ferromagnetic layer 1 and evaluates light reflected by the first ferromagnetic layer 1. If the orientation direction of magnetization changes due to a magnetic Kerr effect, the deflection state of the reflected light changes. For example, the magnetization rotation element 102 can also be used as an optical element, for example, in a video display device or the like utilizing a difference in the deflection state of light.

Furthermore, the magnetization rotation element 102 can also be utilized alone as an anisotropic magnetic sensor, an optical element utilizing a magnetic Faraday effect, or the like.

The magnetization rotation element 102 according to the third embodiment is obtained by simply removing the nonmagnetic layer 3 and the second ferromagnetic layer 2 from the magnetoresistance effect element 100, and an effect similar to that of the magnetoresistance effect element 100 according to the first embodiment is achieved. In the magnetization rotation element 102 according to the third embodiment as well, modification examples similar to those of the magnetoresistance effect element 100 according to the first embodiment can be selected.

### REFERENCE SIGNS LIST

1 First ferromagnetic layer
2 Second ferromagnetic layer
3 Nonmagnetic layer
10 Laminate
20 Spin-orbit torque wiring
31 First electrode
32 Second electrode
33 Third electrode
40 Buffer layer
100, 100A, 100B, 101 Magnetoresistance effect element
102 Magnetization rotation element
200 Magnetic memory
CL Common line
RL Reading line
WL Writing line
In Insulating layer

What is claimed is:

1. A magnetoresistance change element comprising:
a spin-orbit torque wiring; and
a laminate,
wherein the laminate has a first ferromagnetic layer, and
the spin-orbit torque wiring and the first ferromagnetic layer form a Schottky junction.

2. The magnetoresistance change element according to claim 1,
wherein the laminate includes the first ferromagnetic layer, a nonmagnetic layer, and a second ferromagnetic layer, and
the nonmagnetic layer is sandwiched between the first ferromagnetic layer and the second ferromagnetic layer.

3. The magnetoresistance change element according to claim 1,
wherein when a writing current is applied to the spin-orbit torque wiring, an amount of current flowing in the spin-orbit torque wiring is larger than an amount of current flowing in the first ferromagnetic layer.

4. The magnetoresistance change element according to claim 1,
wherein the spin-orbit torque wiring is a semiconductor, and
the first ferromagnetic layer is a metal magnetic body.

5. The magnetoresistance change element according to claim 1 further comprising:
a buffer layer coming into contact with a second surface facing a first surface coming into contact with the first ferromagnetic layer of the spin-orbit torque wiring,
wherein the spin-orbit torque wiring is a p-type semiconductor, and
a work function of the buffer layer is lower than a work function of the spin-orbit torque wiring.

6. The magnetoresistance change element according to claim 1 further comprising:
a buffer layer coming into contact with a second surface facing a first surface coming into contact with the first ferromagnetic layer of the spin-orbit torque wiring,
wherein the spin-orbit torque wiring is an n-type semiconductor, and
a work function of the buffer layer is higher than a work function of the spin-orbit torque wiring.

7. The magnetoresistance change element according to claim 1,
wherein the spin-orbit torque wiring contains an element constituting the first ferromagnetic layer as a dopant.

8. The magnetoresistance change element according to claim 7,
wherein a concentration of the dopant becomes higher the closer to the first ferromagnetic layer.

9. The magnetoresistance change element according to claim 1,
wherein a reading current is constituted to flow from the spin-orbit torque wiring toward the laminate.

10. The magnetoresistance change element according to claim 1,
wherein the first ferromagnetic layer is Co—Fe—B, and
wherein the spin-orbit torque wiring is p-type semiconductor.

11. The magnetoresistance change element according to claim 1 further comprising:
a first electrode; and
a second electrode,
wherein the first electrode is connected to the spin-orbit torque wiring,
the second electrode is connected to the spin-orbit torque wiring at a position at which together with the first electrode it sandwiches the laminate when viewed in a lamination direction, and
at least one of an interface between the first electrode and the spin-orbit torque wiring and an interface between the second electrode and the spin-orbit torque wiring forms an ohmic junction.

12. A magnetic array comprising:
a plurality of magnetoresistance change elements,
wherein at least one of the plurality of magnetoresistance change elements is the magnetoresistance change element according to claim 1.
